(19) United States
(12) Patent Application Publication
(10) Pub. No.: US 2026/0245555 A1
(43) Pub. Date: Aug. 20, 2026

(54) Method and System for Capturing and Displaying Communications Using a Portable Device Generating an Induction Loop Signal

(71) Applicants: NIGEL E. GARDNER, Skillman, NJ (US); EDWARD J.P. HYNES, Princeton, NJ (US)

(72) Inventors: NIGEL E. GARDNER, Skillman, NJ (US); EDWARD J.P. HYNES, Princeton, NJ (US)

(21) Appl. No.: 18/455,323

(22) Filed: Aug. 24, 2023

(51) Int. Cl. G10L 15/26; G06F 1/16; G06F 3/04817; G06F 3/16; G06F 40/58; H04R 1/08; H04R 25/00; H05K 5/02

(52) U.S. Cl. CPC G10L 15/26; G06F 1/1635; G06F 1/1658; G06F 3/04817; G06F 3/162; G06F 40/58; H04R 1/08; H04R 25/554; H05K 5/0204; H04R 2499/15

(57) ABSTRACT

A method and system to capture and process all communications in an interaction. The system can be used by persons without hearing loss and also has the capability to accommodate people who have hearing loss. For people with hearing loss, the system broadcasts an induction loop signal to the person's hearing aid or cochlear implant. The method and system can be used by a patient in a healthcare setting to record, transcribe, translate, and provide closed captioning of all communications between patient and healthcare workers.

### BACKGROUND OF THE INVENTION

Field of the Invention

The present invention relates in general to a method and system to capture and process communications and in particular to a method and system for capture and display of communications including an integrated portable device generating an induction loop signal to assist those with hearing loss. The system can provide closed captioning, recording, translation and transcribing of communications and identifying speakers through voice recognition technology. The data from the communications can be transmitted by email to an approved party, stored in an electronic health medical record or on a web portal for subsequent access by the subject or their families.

### Description of Related Art

Conventional hearing aids and all cochlear implants have an antenna built in the devices. The antenna is referred to as a telecoil or “t-coil”. Originally used to hear better on the telephone, the t-coil has been used in hearing aids to enhance hearing in difficult listening environments. The t-coil is a small copper coil in a hearing aid that functions as a wireless antenna The t-coil can capture an induction loop signal that is broadcast wirelessly by copper wires that have an induction loop signal fed into them. The t-coil can link to a sound system or public address (PA) system which can be found in, theaters, libraries, transit hubs and the like for delivering customized sound to a hearing aid wearer within a loop system.

Many hearing aids are not equipped with a t-coil antenna that would otherwise allow the wearer to receive an induction loop signal which is advantageous for hearing aid systems. US Patent Publication No. 2020/0374387 describes a system including a removable antenna configured to operatively associate with a smart device to receive and transmit magnetic signals broadcast via an induction loop sound source to a hearing aid device by way of the associated smart device. The induction loop signal can be picked up and broadcast by the smart device to a person with a non t-coil equipped hearing aid, a headphone or earbud.

It is desirable to provide a method and system to capture and process all communications in an interaction including induction loop signals and close captioning of the communications and specifically for use in a healthcare setting where accurate and clear communications are critical.

### SUMMARY OF THE INVENTION

The present invention relates to a method and system to capture, store and process all communications in an interaction. The system can be used by a person without hearing and has the capability to accommodate people who have hearing loss. For people with hearing loss, the system broadcasts an induction loop signal to the person's hearing aid or cochlear implant. In one embodiment, the method and system can be used by a patient in a healthcare setting to record, transcribe, translate, and provide closed captioning of all communications between patient and health care workers. The capturing of the communication of a voice recording, translation and a transcription of the voice recording adds value to the person with hearing loss and their families as well as those with normal hearing by providing the opportunity to replay conversation to remind participants of the details of the conversation and to improve understanding. Subsequent analysis of stored data can provide useful information to assist in clinical research, improvement of treatment and outcomes and to inform care management protocols.

In one embodiment, the system provides a closed caption of a voice source as well as the induction loop signal at the same time to significantly improve understanding of words uttered by the voice source. The closed captioning can assist those that are hard of hearing and do not use a t-coil equipped hearing aid or do not have a hearing aid at all. Closed captioning is helpful to all whether with normal, slightly impaired hearing or those without a t-coil equipped hearing aid.

The system can include an integrated portable device. The integrated portable device combines an induction loop signal generator with a tablet computer, such as for example an IPad, to display closed captioning text. The system can provide transcripts, recordings, and translation of communications of conversations that take place through the device. In one embodiment, the recording and transcripts can be accessed by a person with hearing loss, as well as by healthcare providers, through a HIPAA compliant web portal for subsequent access and playback.

In one embodiment, the system provides a video conference between patient and family members. The system can also have the ability for addition of video interpreter and ASL services, transcripts edited by a medical transcription service including url links to appropriate medical terminology. The system can have the ability to provide medications and diagnosis in English or a Foreign language. The system can have the ability to have real time and updated transcripts emailed to Hospital staff and a medical record system, The system can have the ability to use transcription to complete patient forms. The system can have the ability to scan patient ID to identify and unlock the software application of the system. In one embodiment, the system can include one or more of the use of artificial intelligence (AI) to analyze anonymized data captured during the patient encounter, use of a portal to allow a patient and their families to review recordings and transcripts; ability to transmit a screen from a device of the present invention to be mirrored an a Smart TV, use of voice recognition to identify and differentiate speakers using voice recognition. The system of the present invention can be HIPAA and Hitech compliant.

In one embodiment the system of the present invention can use AI to update transcription text to provide corrected extracts or summaries of a patient encounter. The updated transcription can help clinical staff streamline note taking before final approval and submission to an electronic medical record system (EMR).

In one embodiment the system of the present invention can use AI to highlight and hyperlink medical terms from the text transcription. The hyperlink can be accessed to provide definitions and information directed to medical terms so that patients and their families can better understand the meaning of medical terms.

In one embodiment the system of the present invention can use AI to search the internet and/or related databases for clinical data. The clinical data can be used to identify patients that might be eligible for clinical trials. The clinical data can be used for outcomes or case management.

In one embodiment the system of the present invention can provide a secure portal. The secure portal includes an interface to enable patients and their families to access and replay transcripts or recordings and other data to enhance their understanding of communications which have taken place in a medical setting.

In one embodiment, the system of the present invention has the ability to stream data from the portable device to a display, for example the display can be a large screen TV. The display can be positioned in a patient room or elsewhere to enable more participants to view the information presented.

In one embodiment, a portable device includes a harness for supporting a tablet computer and an induction loop housing. The induction loop housing contains an induction loop, loop amplifier, electronics and battery. The harness can be mounted on an IV stand or an articulated arm.

In another embodiment, an integrated portable device includes an assembly of an induction loop housed in a frame housing. The frame housing is coupled around the outside of a tablet computer. The frame housing includes a bezel, front housing and a back housing. The bezel holding the front of the tablet computer. The front housing being positioned at the rear of the tablet computer. The induction loop being housed or integrated into the front housing. The back housing being coupled to the upper housing. The back housing houses a battery for the induction loop and electronics behind the tablet computer. A power source charges both the tablet computer and the battery for the induction loop. The integrated portable device can be mounted to an articulating arm or attached to a movable pole such as is used for an IV.

The invention will be more fully described by reference to the following drawings.

### BRIEF DESCRIPTION OF THE DRAWINGS

FIG. 1 is a schematic view of components of a portable device in accordance with the teaching of the present invention.

FIG. 2 is a schematic diagram of a harness for supporting a tablet and an induction loop housing.

FIG. 3A is a side and front view of a harness for supporting a tablet and an induction loop housing.

FIG. 3B is a front view the harness for supporting a tablet and an induction loop housing.

FIG. 3C is a front view the harness for supporting a tablet and an induction loop housing.

FIG. 4 is a schematic diagram of an induction loop housing.

FIG. 5A is a top view of an interior of an induction loop housing receiving an induction loop and amplifier circuit board.

FIG. 5B is a top view of an interior of an induction loop housing including the induction loop and amplifier circuit board.

FIG. 5 C is a view of the amplifier circuit board.

FIG. 6 is a schematic diagram of an integrated portable device in accordance with the teachings of the present invention.

FIG. 7 is a schematic diagram of the integrated portable device including a bezel, front housing and rear housing.

FIG. 8 is a schematic diagram of the integrated portable device including a bezel, front housing and rear housing receiving a tablet computer and amplifier circuit board.

FIG. 9A is a top view of the back housing.

FIG. 9B is a top view of the back housing including inserts.

FIG. 9C is a bottom view of the back housing.

FIG. 10A is a top view of the bezel.

FIG. 10B is a top view of the bezel including inserts.

FIG. 11A is a top and side view of the integrated portable device.

FIG. 11B is a front view of the integrated portable device showing exposed view of a home button and camera.

FIG. 11C is a bottom view of the integrated portable device.

FIG. 11D is a rear side view of the integrated portable device.

FIG. 11E is a rear side view of the integrated portable device.

FIG. 11F is a right side view of the integrated portable device.

FIG. 11G is a left side view of the integrated portable device.

FIG. 11H is a front view of the integrated portable device.

FIG. 11I is a cross section view along Section A-A shown in FIG. 12H.

FIG. 11J is a cross section view along Section B-B shown in FIG. 12H.

FIG. 11K is a bottom view of the integrated portable device showing exposed electronics bias above a video electronics standards association (VESA) mount.

FIG. 12 is a schematic diagram of audio routing of the portable device in a system of the present invention.

FIG. 13 is a schematic diagram of audio routing of the portable device in a system of the present invention.

FIG. 14A-14C are schematic diagrams of an interface to the tablet computer.

FIG. 15 is a system diagram of a system of the present invention used in healthcare.

Embodiments of the present disclosure and their advantages are best understood by referring to the detailed description that follows. It should be appreciated that the figures may not be necessarily drawn to scale.

### DETAILED DESCRIPTION

Reference will now be made in greater detail to a preferred embodiment of the invention, an example of which is illustrated in the accompanying drawings. Wherever possible, the same reference numerals will be used throughout the drawings and the description to refer to the same or like parts.

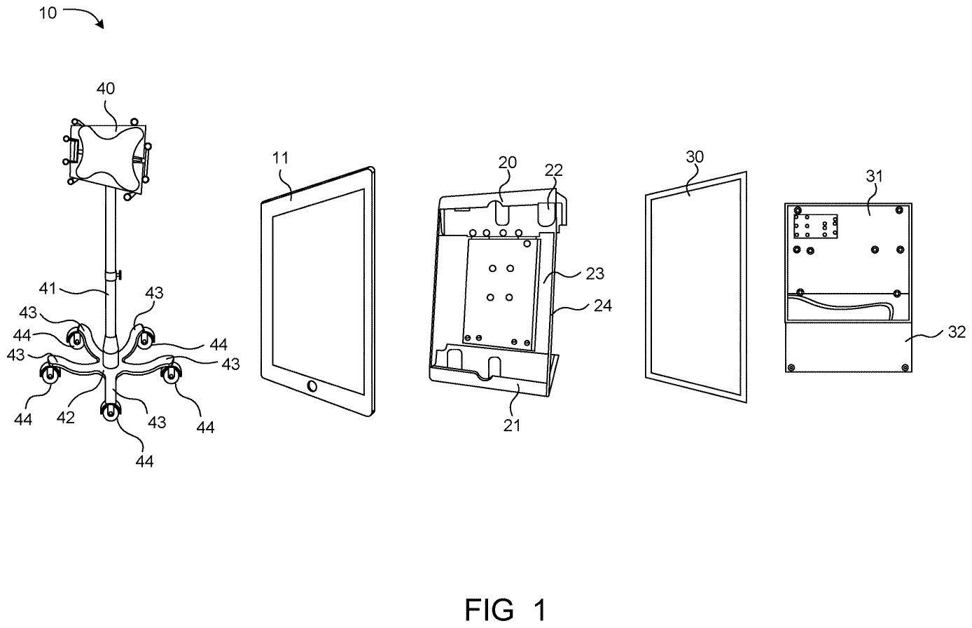

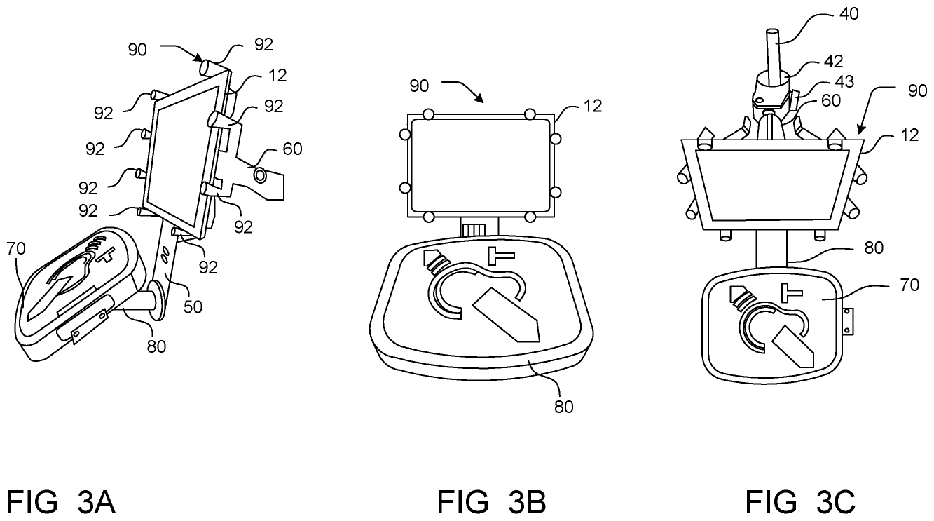

FIG. 1 is a schematic view of components of portable device 10 including processing device 11 in accordance with the teaching of the present invention. Portable device 10 includes processing device 11. Processing device 11 can be a tablet computer, smartphone or laptop. Processing device 11 can be received in holder 20. Processing device 11 can include a mobile operating system, touch screen display, processing circuitry, memory storage within a housing. Example processing devices include Apple IPad, Amazon Fire and Samsung Galaxy Tab. Holder 20 includes lip 21 and lip 22. Mount 23 can be included on rear 24 of holder 20. For example, holder 20 can be a RAM Tab-Tite Holder as manufactured by Ram Mounts and including a AMPS or VESA hole pattern as a mount for mounting of holder 20. Portable device 10 can include induction loop 30, loop amplifier 31 and battery source 32. Induction loop 30 generates an induction loop field connecting wirelessly to telecoil equipped hearing aids, cochlear implants and T-coil receivers. Loop amplifier 31 can amplify an induction signal generated by induction loop 30. Battery source 32 powers loop amplifier 31. Stand 40 can include support pole 41. Support pole 41 can be coupled to support frame 42 including a plurality of arms 43. Roller wheels 44 can be attached to each of arms 43. In one embodiment stand 40 is a an intravenous (IV) pole or IV stand. Stand 40 can support processor device 11 as shown in FIG. 3A.

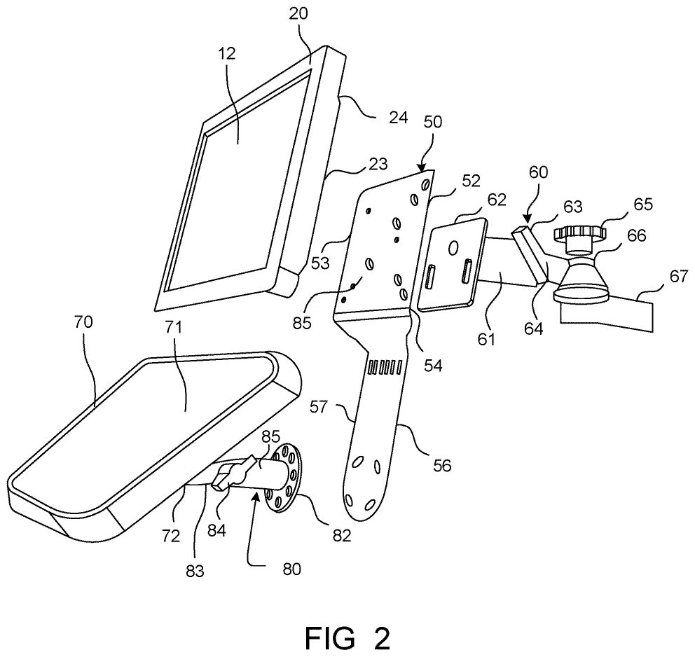

FIG. 2 is a schematic diagram of harness mount 50 for mounting tablet computer to stand 40 or articulated arm 60. Holder 20 extends around tablet 12. Holder 20 can be coupled to front surface 53 of top portion 52 of harness mount 50 for supporting tablet computer 12. Mount 23 can be coupled to mount 55 of harness mount 50. Rear surface 54 of top portion 52 of harness mount 50 can be coupled to articulated arm 60. Articulated arm 60 includes bracket mount 61 coupled or integral with arm bracket 62. Arm bracket 62 can be coupled to rear surface 54 of top portion 52 of harness mount 50. Coupling member 63 can couple bracket mount 61 to front arm 64. Coupling member 65 can be received in joint 66 for coupling front arm 64 to rear arm 67.

Induction loop housing 70 can be coupled to front surface 57 of bottom portion 56 of harness mount 50. Induction loop arm 80 can be attached to rear 72 of induction loop housing 70 and bottom portion 56 of harness mount 50. Induction loop arm bracket 82 can attach to bottom portion 56 of harness mount 50. Induction loop arm 80 can include front arm portion 83 and rear arm portion 85. Arm adjustment member 84 can adjust the positioning of front arm portion 83 and rear arm portion 85 for adjusting placement of induction loop housing 70.

FIG. 3A-3C illustrate harness 90 which can be used for supporting tablet computer 12. Harness 90 can be coupled to harness mount 50. In this embodiment, harness 90 can support tablet computer 12 without including holder 20. Supports 92 are positioned around the edges of harness 90. Supports 92 are used to mount tablet computer 12 in harness 90. Articulated arm 60 is mounted to stand 40 using stand mount 42. Stand mount 42 can be releasably attached to stand 40 with stand mount coupling 43. Stand 40 can include one ore more

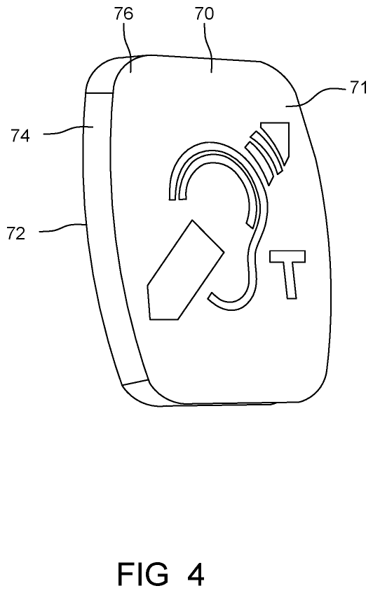

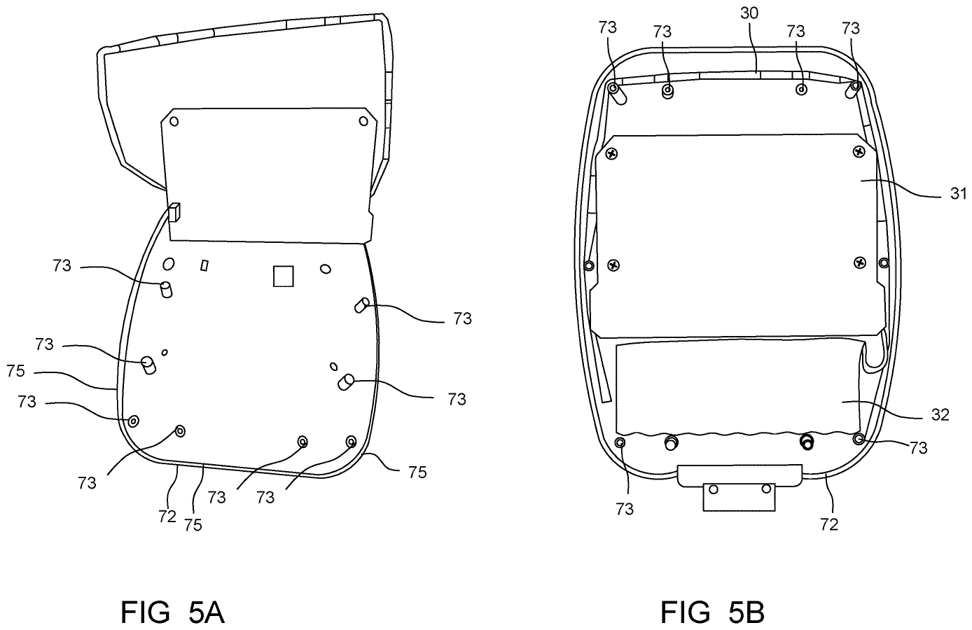

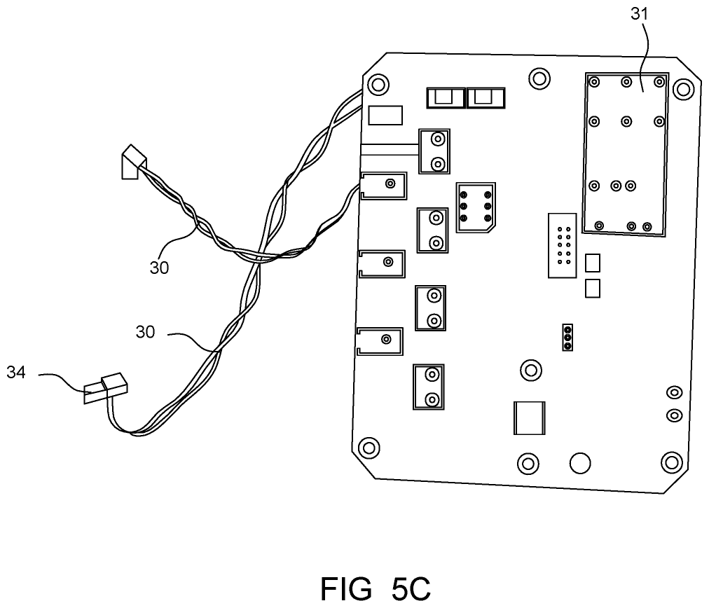

Induction loop housing 70, shown in FIG. 4, can be used to house induction loop 30 and amplifier circuit board 31 and battery source 32, as shown in FIGS. 5A-5C. Amplified circuit board 31 can be used to amplify the signal of induction loop 30. For example, amplified circuit board 31 can be manufactured by Emcom systems as model number 925835. Induction loop housing 70 can include bottom housing 74 which snaps into top housing 76 or is integral therewith, as shown in FIG. 4.

Referring to FIGS. 5A-5B, supports 73 can protrude upwardly from inner surface 77 of bottom housing 74. Supports 73 are positioned adjacent walls 75 of bottom housing. Induction loop 30 extends around supports 73 as shown in FIG. 5B. Amplifier circuit board 31 and battery source 32 can be coupled to bottom housing 74. Induction loop connector 34 can extend from induction loop 30 as shown in FIG. 5C.

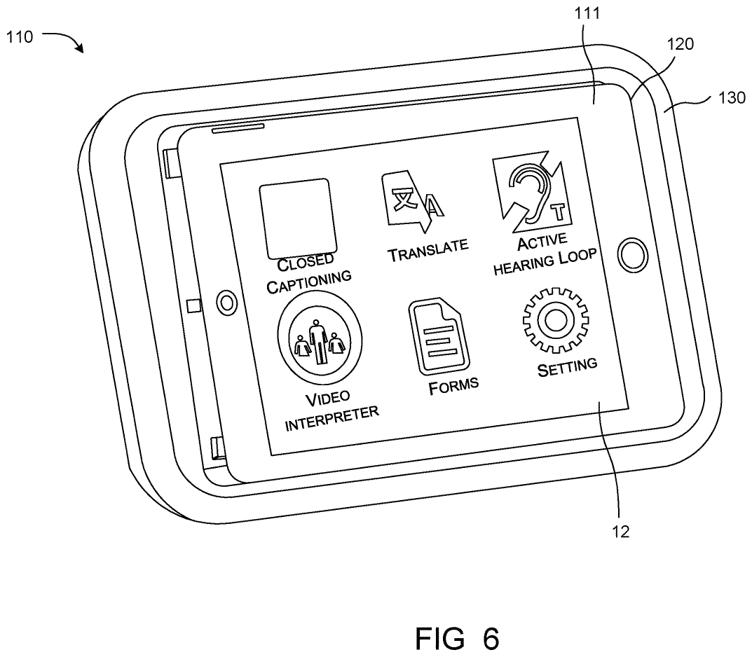

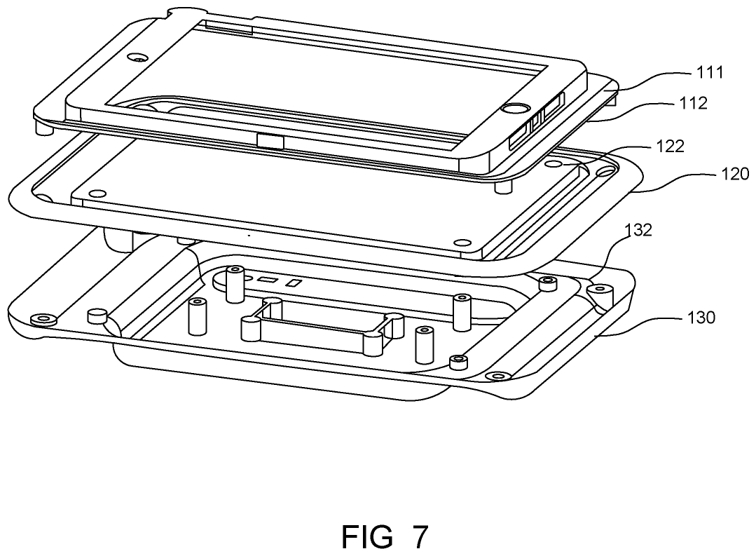

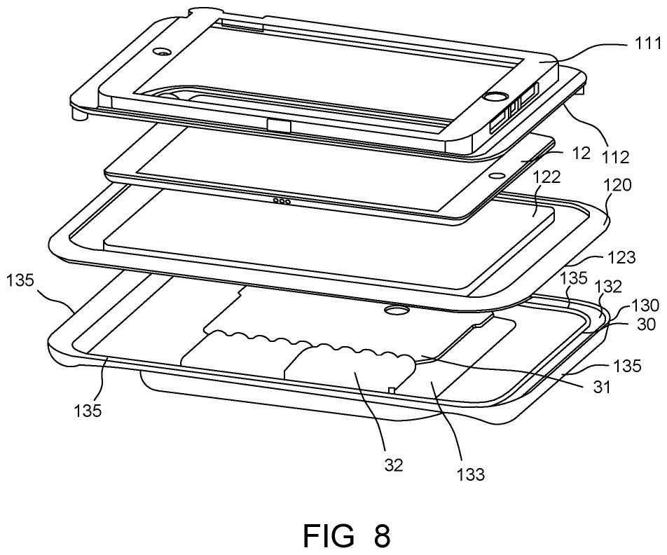

FIG. 6 is a schematic diagram of integrated portable device 110. Tablet computer is 12 is held by bezel 111 within integrated portable device 110. Referring to FIGS. 7 and 8, integrated portable device includes bezel 111, front housing 120 and back housing 130. Tablet computer 12 is positioned between rear surface 112 of bezel 111 and top surface 122 of front housing 120. Top surface 132 of back housing 130 can be coupled to rear surface 123 of front housing 120. Amplifier circuit board 31 and battery source 32 can be coupled to interior surface 133 of back housing 130. Induction loop 30 can extend around interior surface 133 adjacent to walls 135 of back housing 130.

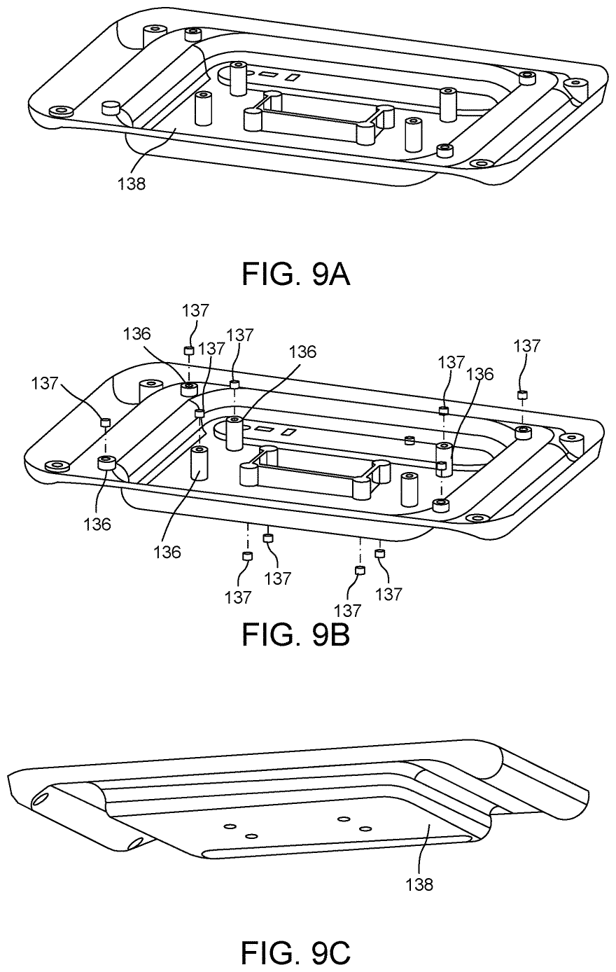

Referring to FIGS. 9A-9C back housing 130 can include supports 136 extending from interior surface 133. Supports 126 can be coupled to front housing 120 using inserts 137. Inserts 137 can be inserted to be flush with rear 138 of back housing 130.

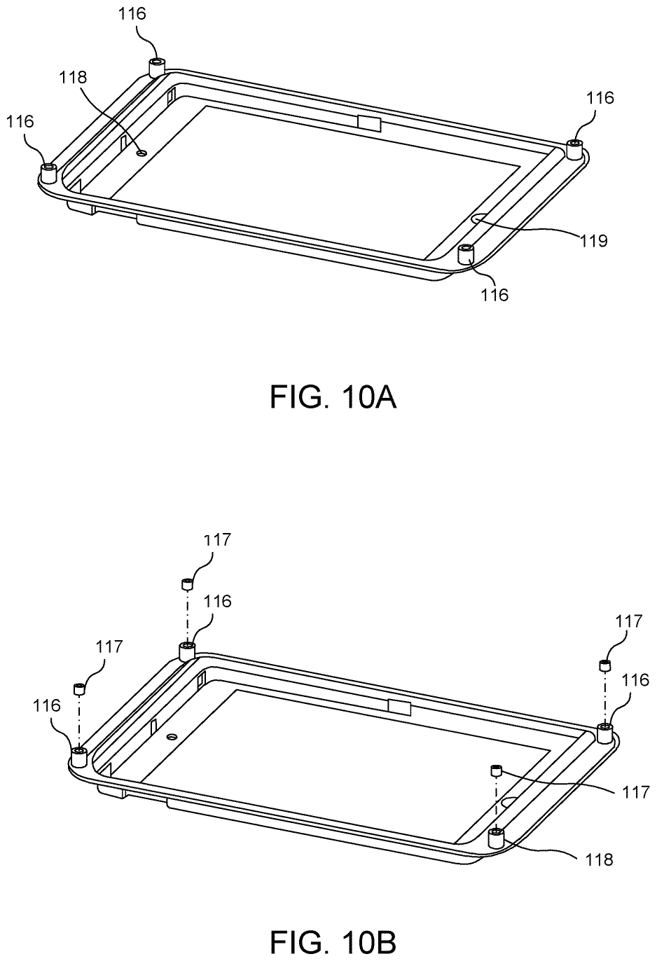

Referring to FIGS. 10A-10B, bezel 111 can include supports 116 extending from interior surface 113. Supports 116 can be coupled to front housing 120 using inserts 117. Inserts 117 can be inserted to be flush with bezel 111. Bezel 111 can be removed from front housing 120 with inserts 117 while front housing 120 is attached to back housing 130 so that induction loop 30, amplifier circuit board 31 and battery source 32 are not exposed when changing of tablet computer 12. Front housing 120 and back housing 130 can be attached from the top under tablet computer 12 to prevent someone from removing the wrong inserts during changing of tablet computer 12.

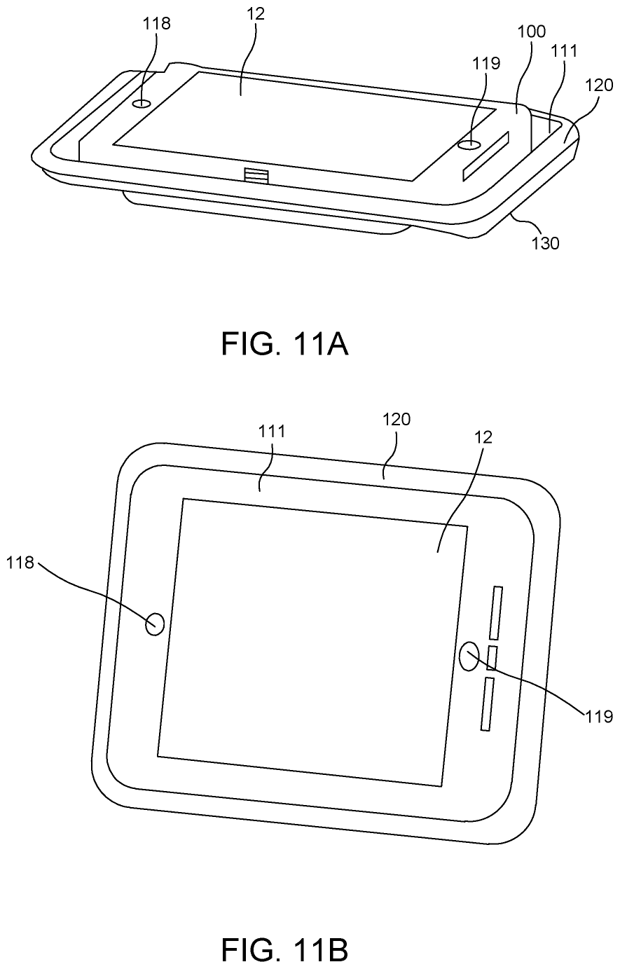

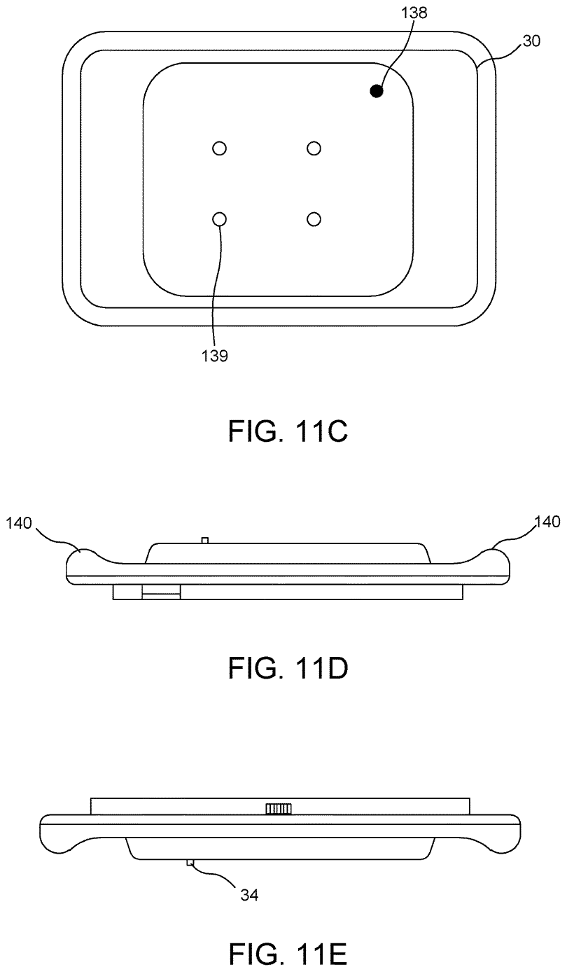

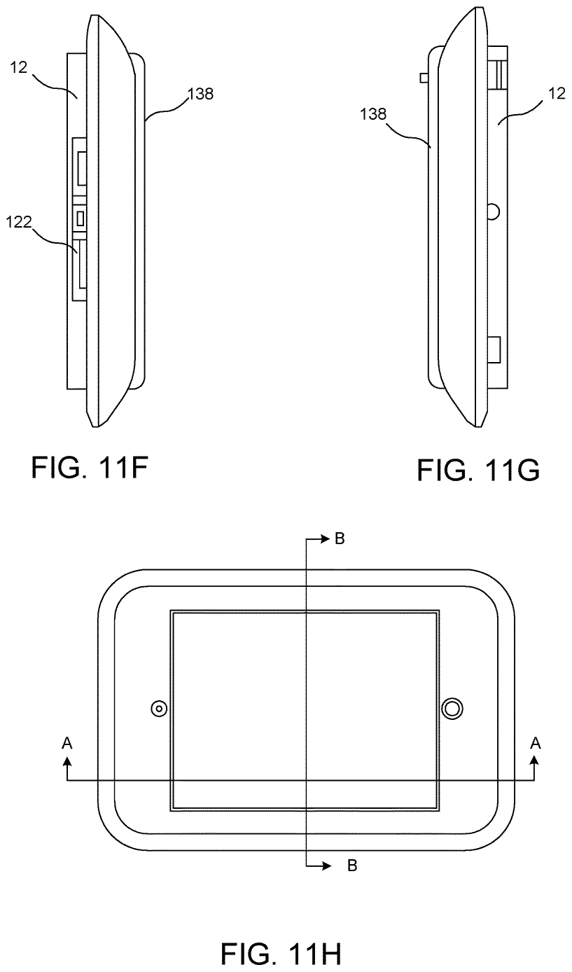

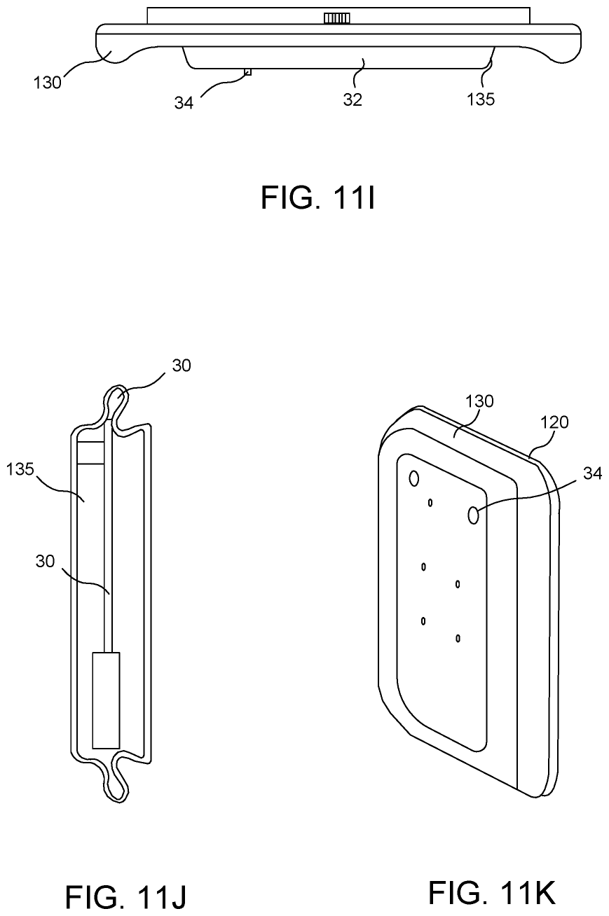

FIGS. 11A-11J illustrate integrated portable device 110. As shown in FIGS. 11A-11B, bezel 111 can include opening 118 to expose a camera of tablet computer 12 and opening 119 to expose a home button of tablet computer 12. As shown in FIG. 11C, induction loop 30 is positioned outboard of tablet computer 12. Electronics pocket 138 can house induction loop 30, amplifier circuit board 31 and battery source 32. Back housing 130 can include VESA mounting 129. As shown in FIGS. 11D and 11E, bezel 111, front housing 120 and back housing 130 can be shaped to include side grips 140. Induction loop connector 34 can extend from back housing 120.

Referring to FIGS. 11E and 11F, front housing 130 can include access ports 129 for access to a lightning or USB C or similar connector. Referring to FIGS. 11H-11J , induction loop 30 extends around back housing 130 adjacent to walls 135. Referring to FIG. 11K, a perimeter of front housing 120 can be flush to the bottom of tablet computer 12 for port access.

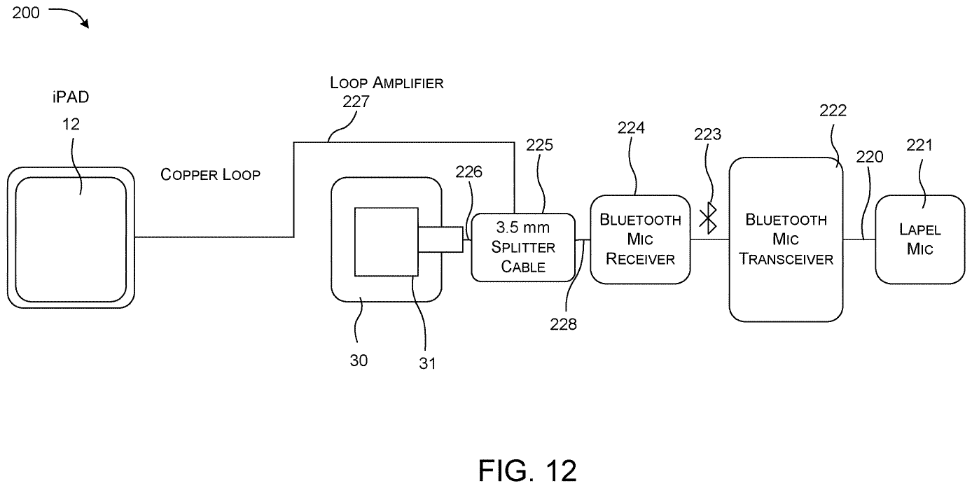

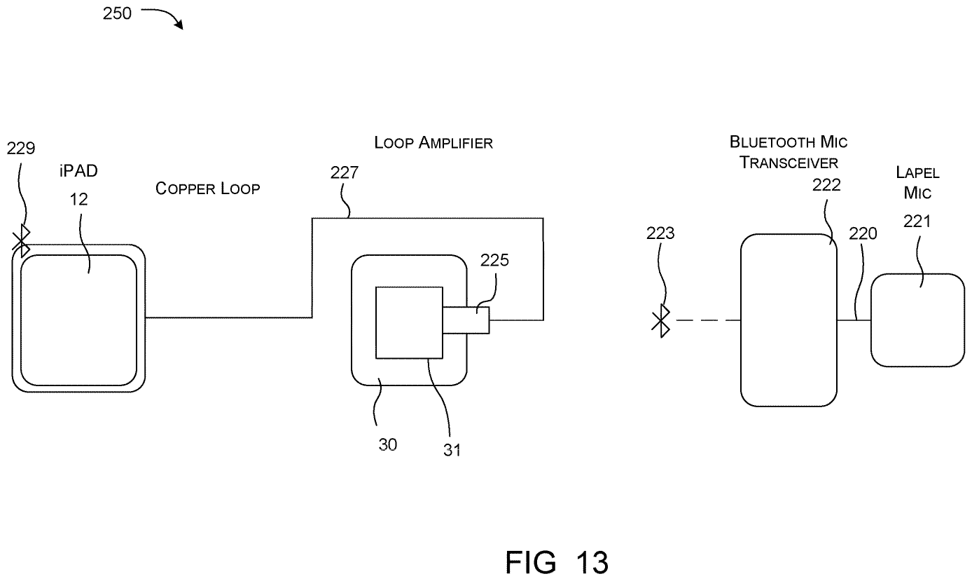

FIG. 12 is a schematic diagram of an embodiment of audio routing of portable device 10 or integrated portable device 100 in system 200. Microphone 221 sends communication over connection 220 to microphone transceiver 222. Microphone 221 can be a lapel microphone. Microphone transceiver 222 can be a Bluetooth receiver. Microphone transceiver 222 sends communications over communications connection 223 to microphone receiver 224. Communications connection 223 can be a wireless Bluetooth connection. Splitter cable 225 connects microphone receiver 224, amplifier circuit board 31 and tablet computer 12 using respective connections 228, 226 and 227. Additionally where the cost of Bluetooth transmitters and microphones are greater than the use case permits wired connections can be used to collect the audio for use in the tablet and induction loop system as indicated below.

FIG. 13 is a schematic diagram of an embodiment of audio routing of portable device 10 or integrated portable device 100 in system 250. Tablet computer 12 communicates with wireless antenna 229 to microphone transceiver 222. Wireless antenna 229 can use Bluetooth to communicate with communication connection 223. Splitter cable 225 connects amplifier circuit board 31 to tablet computer 12 over connection 227.

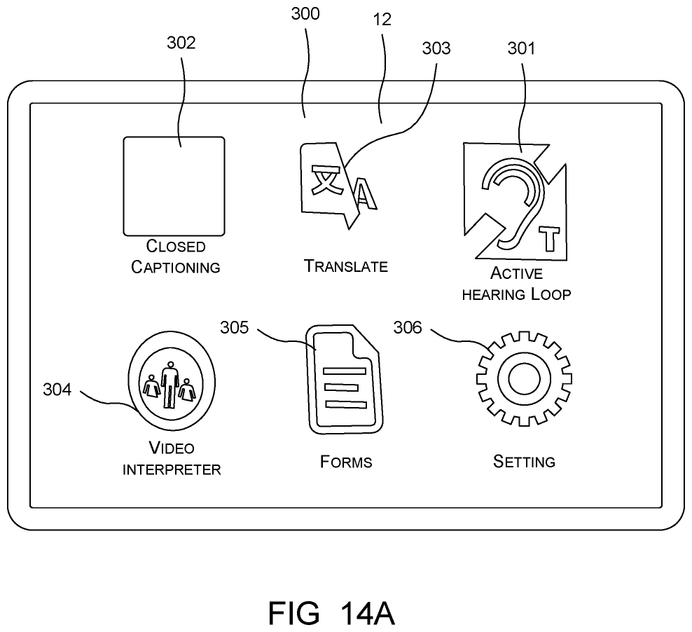

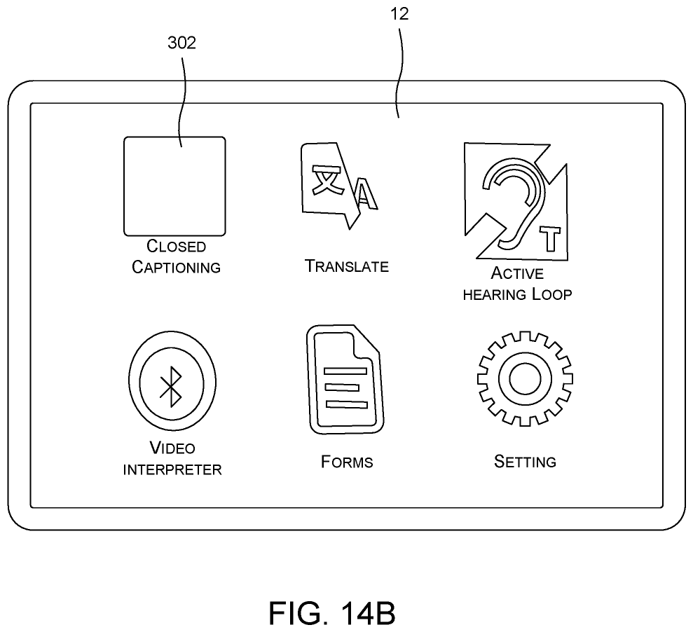

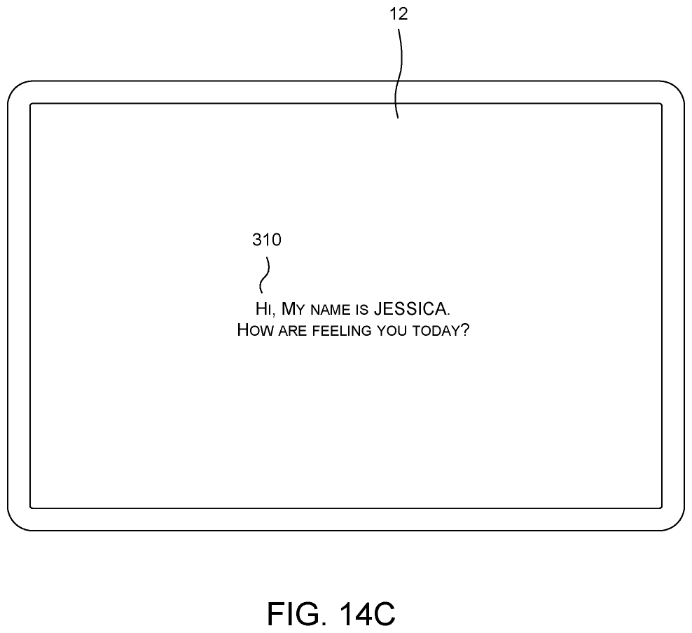

FIGS. 14A-14C illustrate graphical user interface 300 which can be used with tablet computer 12. Graphical user interface 300 includes activate induction loop icon 301, closed captioning icon 302, translate icon 303, video interpreter icon 304, forms icon 305 and settings icon 306. As shown in FIG. 14B, closed captioning icon 302 can be clicked to activate closed caption features generated by tablet computer 12. Video interpreter icon 304 can be clicked to activate video interpretation features generated by tablet computer 12. Forms icon 305 can be clicked to generate one or more forms or templates by tablet computer 12. Audio input is captured in real time using system 200 or system 250 and captioned in real time to be displayed as indicia 310 on tablet computer 12. For example, indicia 310 can be displayed in black on a white background. Settings icon 303 can access settings of tablet computer 12.

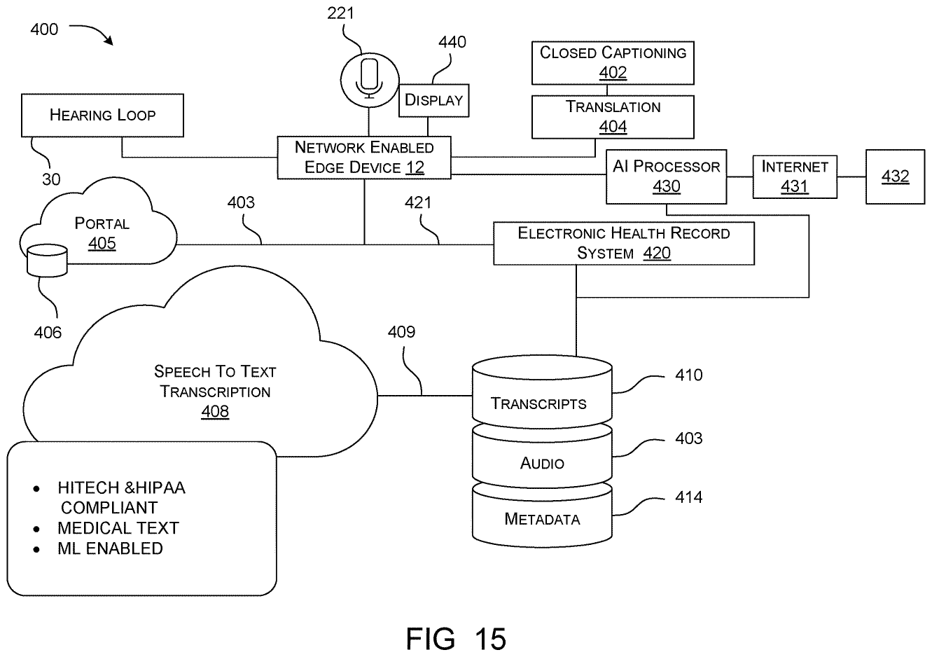

FIG. 15 is a systems diagram of system 400. System 400 can be used in health care. Closed captioning processing 402 can be accessed by closed captioning icon 302 to provide closed captions of captured speech. For example closed captioning processing can be implemented with Google Voice. Translation processing 404 can be accessed by translate icon 303 to provide translation of captured speech. Closed captioning processing 402 and translation processing 404 can be performed at tablet computer 12. Audio data 403 received by tablet computer 12 can be stored using portal 405 to one or more databases 406. Portal 405 can be a secure portal requiring authorization for use, such as for example by a patient or health care provider. Speech to text transcription processing 408 can be performed to transcribe audio data 403 to text transcription 409. Text transcription 409 can be compliant with HIPAA, HITECH and HITRUST, include medical text and be ML enabled. System 420 can use text transcription 409 to complete patient forms. Transcripts 410 of text transcription 409, audio 403 and meta data 414 can be forwarded to electronic health record system 420. For example, health record system is a electronic medical record system (EMR). Electronic health record system 420 can forward health records 421 to tablet computer 12. Health records 421 can include transcripts 410, audio 403 and meta data 414. System 420 using health records 421 can provide medications and diagnosis in English or a Foreign language. System 420 using tablet computer 12 can email in real time updated transcripts to Hospital staff and electronic health record system 420. Tablet 12 can scan a patient ID to identify and unlock a software application of system 420. In one embodiment, system 420 and/or tablet computer 12 can include one or more of the use of artificial intelligence (AI) to analyze anonymized data captured during the patient encounter, a display of tablet computer 12 or portal 405 is used as a portal to allow a patient and their families to review recordings and transcripts; tablet computer 12 transmits a screen to be mirrored on a Smart TV and use of voice recognition by tablet computer 12 to identify and differentiate speakers using voice recognition.

In one embodiment, system 400 uses AI processor 430 to update text transcription 409 using AI. For example, updated text transcription 409 can provide corrected extracts or summaries of a patient encounter.

In one embodiment, system 400 uses AI processor 430 to highlight and hyperlink medical terms from text transcription 409. The hyperlink can be accessed to provide definitions and information directed to medical terms so that patients and their families can better understand the meaning of medical terms.

In one embodiment, system 400 uses AI processor 430 to search internet 431 and/or related databases 432 for clinical data. The clinical data can be used to identify patients that might be eligible for clinical trials. The clinical data can be used for outcomes or case management.

In one embodiment, portal 405 is a secure portal. Portal 405 includes an interface to enable patients and their families to access and replay text transcriptions 409 or recordings of audio 403 and other data to enhance their understanding of communications which have taken place in a medical setting.

In one embodiment, system 400 streams data from portable device 12 to a display 440. For example, display 440 computer an be a large screen TV.

Embodiments of the present invention can be implemented in connection with a processor including a AI processor and other processors for performing features of system 200, 250 and 400 which can include a special purpose or general purpose computer device that includes both hardware and/or software components, including special purpose or general purpose computers.

Embodiments can also include physical computer-readable media and/or intangible computer-readable media for carrying or having computer-executable instructions, data structures, and/or data signals stored thereon. Such physical computer-readable media and/or intangible computer-readable media can be any available media that can be accessed by a general purpose or special purpose computer. By way of example, and not limitation, such physical computer-readable media can include RAM, ROM, EEPROM, CD-ROM or other optical disk storage, magnetic disk storage or other magnetic storage devices, other semiconductor storage media, or any other physical medium which can be used to store desired data in the form of computer-executable instructions, data structures and/or data signals, and which can be accessed by a general purpose or special purpose computer. Within a general purpose or special purpose computer, intangible computer-readable media can include electromagnetic means for conveying a data signal from one part of the computer to another, such as through circuitry residing in the computer. When information is transferred or provided over a network or another communications connection (either hardwired, wireless, or a combination of hardwired or wireless) to a computer, hardwired devices for sending and receiving computer-executable instructions, data structures, and/or data signals (e.g., wires, cables, optical fibers, electronic circuitry, chemical, and the like) should properly be viewed as physical computer-readable mediums while wireless carriers or wireless mediums for sending and/or receiving computer-executable instructions, data structures, and/or data signals (e.g., radio communications, satellite communications, infrared communications, and the like) should properly be viewed as intangible computer-readable mediums. Combinations of the above should also be included within the scope of computer-readable media.

Computer-executable instructions include, for example, instructions, data, and/or data signals which cause a general purpose computer, special purpose computer, or special purpose processing device to perform a certain function or group of functions. Although not required, aspects of the invention have been described herein in the general context of computer-executable instructions, such as program modules, being executed by computers, in network environments and/or non-network environments. Generally, program modules include routines, programs, objects, components, and content structures that perform particular tasks or implement particular abstract content types. Computer-executable instructions, associated content structures, and program modules represent examples of program code for executing aspects of the methods disclosed herein.

While the subject matter has been described above in the general context of computer-executable instructions of a program that runs on one or more computers, those skilled in the art will recognize that the subject matter described herein also can be implemented in combination with other program modules. Generally, program modules include routines, programs, components, data structures, etc. that perform particular tasks and/or implement particular abstract data types. Moreover, those skilled in the art will appreciate that the inventive methods can be practiced with other computer system configurations, including single-processor, multiprocessor or multi-core processor computer systems, mini-computing devices, mainframe computers, as well as personal computers, hand-held computing devices (e.g., personal digital assistant (PDA), phone, watch), microprocessor-based or programmable consumer or industrial electronics, and the like. The illustrated aspects can also be practiced in distributed computing environments where tasks are performed by remote processing devices that are linked through a communications network. However, some, if not all aspects of the claimed subject matter can be practiced on stand-alone computers. In a distributed computing environment, program modules can be located in both local and remote memory storage devices.

Embodiments may also include computer program products for use in the systems of the present invention, the computer program product having a physical computer-readable medium having computer readable program code stored thereon, the computer readable program code comprising computer executable instructions that, when executed by a processor, cause the system to perform the methods of the present invention.

It is to be understood that the above described embodiments are illustrative of only a few of the many possible specific embodiments, which can represent applications of the principles of the invention. Numerous and varied other arrangements can be readily devised in accordance with these principles by those skilled in the art without departing from the spirit and scope of the invention.

What is claimed is:

1. A system for capturing and displaying communications comprising:
a portable device comprising a processing device and an induction loop; and
the processing device including a display.

2. The system of claim 1 wherein the portable device further comprises a loop amplifier, the loop amplifier amplifying a signal from the induction loop.

3. The system of claim 2 wherein the portable device further comprises a power source, the power source powering the loop amplifier.

4. The system of claim 3 wherein the portable device further comprises a housing, the housing including a top and a bottom, an inner surface of the bottom of the housing including a plurality of supports positioned around a circumference of the inner surface of the bottom of the housing, the induction loop extending around the supports, and the loop amplifier and the battery source being coupled to the inner surface of the bottom of the housing, and the top of the housing being coupled to the bottom of the housing.

5. The system of claim 4 wherein the portable device further comprises a holder or harness for supporting the processing device, a mount coupled to the holder or harness and to the induction loop housing, an arm mount having a first end coupled to the mount and a second end configured to be mounted on a stand or an articulated arm.

6. The system of claim 3 wherein the portable device is an integrated portable device, the integrated portable device comprising a bezel, front housing and back housing, the processing device is a tablet computer, a rear surface of the bezel and top surface of the front housing configured to receive the processing device, a top surface of the back housing removably coupled to the rear surface of the front housing, the loop amplifier and the power source coupled to an interior surface of the back housing, and the induction loop extending around the interior surface adjacent to walls of the back housing.

7. The system of claim 1 further comprising a microphone and a microphone receiver wherein the microphone receiver sends communications from the microphone to the processing device.

8. The system of claim 1 wherein the processing device having memory storage or being connected to one or more storage devices for storing the communications.

9. The system of claim 1 wherein the processing device having a graphical user interface, graphical user interface including one or more of activate induction loop icon, closed captioning icon, translate icon, video interpreter icon, forms icon and settings icon wherein the closed captioning icon being configured to activate closed caption features, the translate icon being configured to activate translation features, the video interpreter icon being configured to activate video interpretation features and the forms icon being configured to generate one or more forms.

10. The system of claim 9 wherein the communications are captured in real time using the system and closed captions are displayed in real time using the closed caption features, the closed captions being displayed as indicia on the display of the processing device.

11. A portable device for capturing communications comprising:
a processing device,
an induction loop; and
a loop amplifier, the loop amplifier amplifying a signal from the induction loop.

12. The portable device of claim 11 wherein the portable device further comprises a power source, the power source powering the loop amplifier.

13. The portable device of claim 11 wherein the portable device further comprises a housing, the housing including a top and a bottom, an inner surface of the bottom of the housing including a plurality of supports positioned around a circumference of the inner surface of the bottom of the housing, the induction loop extending around the supports, and the loop amplifier and the battery source being coupled to the inner surface of the bottom of the housing, and the top of the housing being coupled to the bottom of the housing.

14. The portable device of claim 11 wherein the portable device further comprises a holder or harness configured for supporting the processing device, a mount coupled to the holder or harness and to the induction loop housing, an arm mount having a first end coupled to the mount and a second end configured to be mounted on a stand or an articulated arm.

15. The portable device of claim 11, wherein the portable device is an integrated portable device, the integrated portable device comprising a bezel, front housing and back housing, the processing device is a tablet computer, a rear surface of the bezel and top surface of the front housing configured to receive the processing device, a top surface of the back housing removably coupled to the rear surface of the front housing, the loop amplifier and the power source coupled to an interior surface of the back housing, and the induction loop extending around the interior surface adjacent to walls of the back housing.

16. The portable device of claim 11 wherein the processing device having a graphical user interface, the graphical user interface including one or more of activate induction loop icon, closed captioning icon, translate icon, video interpreter icon, forms icon and settings icon wherein the closed captioning icon being configured to activate closed caption features, the translate icon being configured to activate translation features, video interpreter icon being configured to activate video interpretation features, forms icon being configured to generate one or more forms wherein the communications are captured in real time using the portable device and the communications are captioned using the closed caption features, the video is interpreted using the video interpretation features and the one or more forms are generated in real time and displayed on a display of the processing device.

17. An integrated portable device comprising;
a frame housing, the frame housing comprising a bezel, front housing and a back housing, the bezel removably attached to the front housing and configured for holding a tablet computer received between the bezel and the front housing;
an induction loop being housed or integrated into the front housing or the back housing; and
the back housing being coupled to the upper housing, the back housing configured for housing received or integral electronics and a power source,
wherein the induction loop electronics and power source are not exposed when the bezel is removed.

18. The integrated portable device of claim 17 wherein the induction loop extends around the back housing adjacent to inner walls of the back housing and the front housing and back housing include side grips on either side of the back housing and the front housing.

19. A system for capturing communications comprising;
a portable device receiving audio data of the communications;
speech to text processing means for converting the audio data to a text transcription;
storage means for storing the audio data and the text transcription;
an electronic health record system generating and storing health records, the health records being accessed by the processing device, the health records including one or more of the text transcription, the audio data and meta data associated with the transcription; and
optionally a translation processing means for translating the audio data into a translation, the storage means storing the translation.

20. The system of claim 19 wherein the portable device comprises:
a processing device;
an induction loop; and
a loop amplifier, the loop amplifier amplifying a signal from the induction loop.

21. The system of claim 20 wherein the processing device comprising a graphical user interface, the graphical user interface including one or more of activate induction loop icon, closed captioning icon, translate icon, video interpreter icon, forms icon and settings icon wherein the closed captioning icon being configured to activate closed caption features, the translate icon being configured to activate translation features, video interpreter icon being configured to activate video interpretation features, forms icon being configured to generate one or more forms wherein the communications are captured in real time using the portable device and the communications are captioned using the closed caption features, the video is interpreted using the video interpretation features or the one or more forms are generated in real time and displayed on a display of the processing device, wherein the system records, transcribes, translates, and provides closed captioning of all communications between a patient and one or more healthcare workers.
